(19) United States
(12) Patent Application Publication
(10) Pub. No.: US 2007/0268740 A1
(43) Pub. Date: Nov. 22, 2007

(54) Ultra low power SRAM cell design

(76) Inventors: Rami E. Aly, Lafayette, LA (US); Magdy A. Bayoumi, Lafayette, LA (US)

Correspondence Address: KEAN, MILLER, HAWTHORNE, D'ARMOND,;MCCOWAN & JARMAN, L.L.P., ONE AMERICAN PLACE, 22ND FLOOR, P.O. BOX 3513, BATON ROUGE, LA, 70821, US

(21) Appl. No.: 11/801,848

(22) Filed: May 11, 2007

Related U.S. Application Data
(60) Provisional application No. 60/800,246, filed on May 12, 2006.

(51) Int. Cl. G11C 11/00

(52) U.S. Cl. 365/154

(57) ABSTRACT

A semiconductor SRAM cell is provided and includes two back-to-back inverters and two p-channel (PMOS) access transistors. In one preferred embodiment the sources of two pull down n-channel (NMOS) transistors are connected to the drain of the ground NMOS transistor, which is connected to ground. During write operation the ground transistor is turned off and the sources of the pull down transistors are floating with high impedance. The precharge circuit is still active and both bit lines are driven “high” with low impedance. The PMOS access transistors are turned on. The two cell nodes are precharged “high.” The precharge cycle is deactivated and the write circuit is activated to transfer a small voltage difference between the bit lines, which is transferred to the cell nodes. Then the access transistors are turned off and the ground transistor is activated to amplify the small voltage difference on the cell nodes.

### BACKGROUND OF THE INVENTION

(1) Field of the Invention

Embodiments of the present invention relates to semiconductor memory cell design. More specifically, embodiments of the present invention relates to low power static random access memory (SRAM) cell design with two back to back cross coupled inverters.

(2) Description of the Prior Art

SRAM represents a large portion of the chip and it is expected to increase in future in both portable devices and high-performance processors. Therefore, low power SRAM memory design is essential to achieve higher reliability and longer battery life.

FIG. 1 shows a conventional CMOS 6T SRAM cell 10 which comprises two inverters, 11 and 12, connected back-to-back and two access transistors. The first inverter 11 consists of n-channel (NMOS) transistor N1 and p-channel (PMOS) transistor P1; while inverter 12 consists of n-channel (NMOS) N2 and p-channel (PMOS) P2. The two back-to-back inverters 11 and 12 provide a positive feedback mechanism so that the SRAM cell works as a bi-stable multivibrator. The two inverters 11 and 12 are connected together such that the input of inverter 12 is connected to output of inverter 11 to form cell node Q 13. The input of inverter 11 is connected to output of inverter 12 to form cell node QB 14. Cell nodes 13 and 14 voltages determine the cell data. When Q 13 is “high”, then QB 14 is “low” and vise versa. The sources of the two pull up PMOS transistors P1 and P2 are connected to supply voltage V_{DD}; while the sources of the two pull down NOMOS transistors N1 and N2 are connected to ground. The two access n-channel (NMOS) transistors N3 and N4 connect the cell nodes Q 13 and QB 14 to bit line pair BL and BLB, respectively. Bit lines are used to transfer data to and from the cell on read and write operations, respectively. The word line WL controls the access transistors N3 and N4 to determine when to access the cell nodes for read or write.

For a stable write operation, driving one of the bit lines to “0” and its complement to “1” are necessary to fight the feedback connection in the conventional SRAM cell. For a write operation, a large part of the total power consumption is dissipated in charging and discharging the large bit lines capacitance to full voltage swing, e.g. V_{DD}. The bit lines' power consumption is expressed as follows:
P_{Conventional}=(C_{BL}V_{DD})V_{DD}F_{write}.

Where C_{BL} is the bit line capacitance, and F_{write} is the frequency of write operation.

The key idea depends on floating the sources of the two pull down NMOS transistors of the conventional 6T SRAM cell to allow using a small voltage difference on the bit line pair during a write operation. Although this technique reduces the write power consumption, using V_{DD}/2 as the precharge voltage of the bit lines strongly reduces the static noise margin SNM of the cell.

### SUMMARY OF THE INVENTION

The principle object of the present invention is to provide a memory cell that reduces power consumption during a write operation by reducing the required voltage swing on the bit lines, and maintains the static noise margin SNM as the conventional SRAM cell. This invention provides a novel semiconductor SRAM cell that comprises two back-to-back inverters and two p-channel (PMOS) access transistors. The sources of the two pull down n-channel (NMOS) transistors are connected together to the drain of another n-channel (NMOS) transistor, named ground transistor; while the source of the ground transistor is connected to the ground. During write operation, the ground transistor is turned off and, therefore the sources of the two pull down transistors are floating with high impedance. The precharge circuit is still active and both bit lines are driven “high” with low impedance, the two PMOS access transistors are turned on to connect the cell nodes to the bit lines. The two cell nodes are also precharged “high”. The precharge cycle is deactivated and the write circuit is activated to transfer a small voltage difference between the bit lines which is directly transferred to the cell nodes. Then, the two PMOS access transistors is turned off and the ground transistor is activated to amplify the small voltage difference on the cell nodes to full swing only inside the cell.

A further object of the present invention is to provide a CMOS SRAM cell which maintains the cell performance, i.e. read and write delay, and the static noise margin SNM as that for the conventional 6T SRAM cell.

A further object of the present invention is to provide a CMOS SRAM cell that ensures a stable read and write operations.

A further object of the present invention is to provide a dual-port version of the low power SRAM cell in this invention.

### BRIEF DESCRIPTION OF THE DRAWINGS

FIG. 1 illustrates a conventional six transistors SRAM memory cell.

FIG. 2 illustrates a schematic of the first preferred embodiment of this invention showing a six transistors SRAM cell.

FIG. 3 illustrates a schematic of a row of the memory array of the preferred cells shown in FIG. 2.

FIG. 4 illustrates a two WRITE, Write “0” followed by Write “1”, operations using first write mode.

FIG. 5 illustrates a two WRITE, Write “0” followed by Write “I”, operations using second write mode.

FIG. 6 illustrates a schematic of a two ports SRAM cell according to the second preferred embodiment of the present invention.

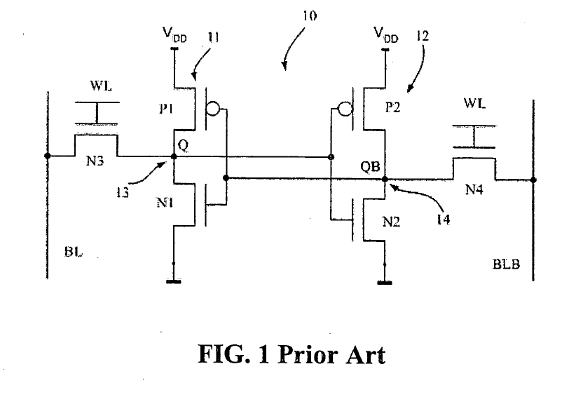

### DETAIL DESCRIPTION OF THE PREFERRED EMBODIMENTS

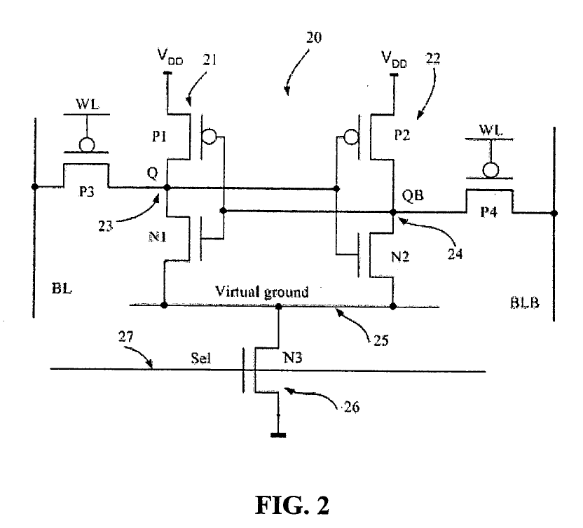

The preferred embodiment of the present invention discloses a novel SRAM cell shown in FIG. 2. The SRAM cell 20 comprises two inverters connected back-to-back to form a bi-stable flip flop, two p-channel (PMOS) access transistors, and two cell nodes Q 23 and QB 24. The SRAM cell 20 further comprises a virtual ground node 25 and n-channel (NMOS) transistor N3 26 which is shared between many cells which are connected to the same virtual ground node 25. The first inverter 21 comprises an n-channel (NMOS) transistor NI and a p-channel (PMOS) transistor P1; while the second inverter 22 comprises an n-channel (NMOS) N2 and a p-channel (PMOS) P2. The source of the two pull up PMOS transistors P1 and P2 are connected to a supply voltage V_{DD}. The sources of the two pull down NMOS transistors N1 and N2 are connected to the virtual ground node 25 which is connected to the drain of n-channel (NMOS) transistor N3 26. The source of N3 26 is connected to real ground, and the gate is connected to Sel signal 27 to control turning N3 26 on and off. Transistor N3 26 has double functionality. It is used during a write operation to allow storing a small swing signal and during a sleep mode to reduce the leakage power.

The two access p-channel (PMOS) transistors P3 and P4 are controlled by the word line WL. If WL is high, then both P3 and P4 are OFF. When WL is low, both P3 and P4 are ON and the bit line pair BL and BLB are connected to the two cell nodes Q 23 and QB 24, respectively. Using PMOS access transistors P3 and P4 allows precharging the bitlines to V_{DD} during a precharge cycle and therefore, the proposed cell can maintain the static noise margin SNM as the conventional cell after careful transistors sizing.

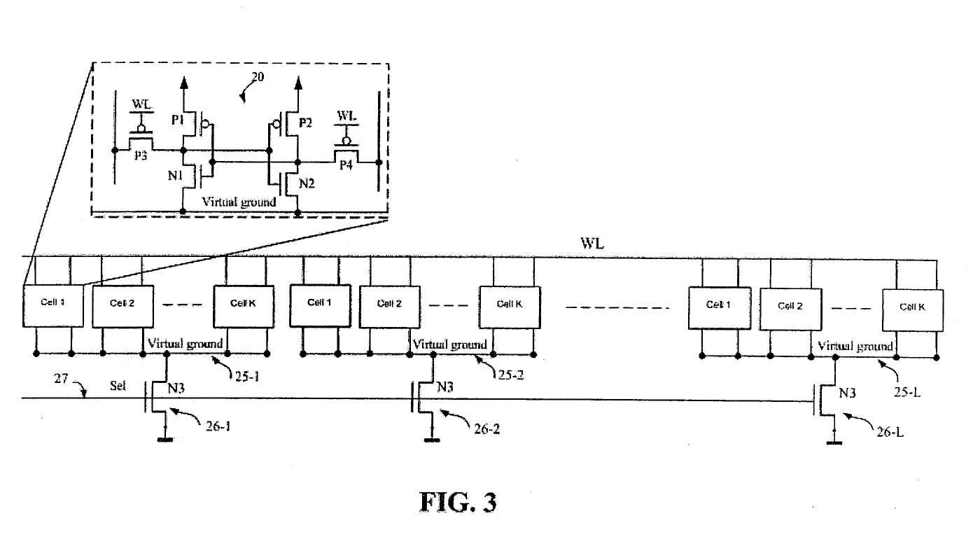

FIG. 3 shows a row of the memory array of the preferred SRAM cells in FIG. 2. The cells in each row are divided into L groups, where each group comprises K cells. K can be two, four, eight, sixteen and it is a tradeoff between the array area and read delay of the cell. The sources of pull down transistors of all the cells in a group are attached together to one virtual ground node. The row has L virtual ground nodes from 25-1 to 25-L. Each group has one n-channel (NMOS) N3; and therefore a row has L times N3 transistors from 26-1 to 26-L. All the cells in a row are connected to one word line WL to control the access PMOS transistors for all cells of the row, and one Sel signal 27 to control all N3 transistors of the row.

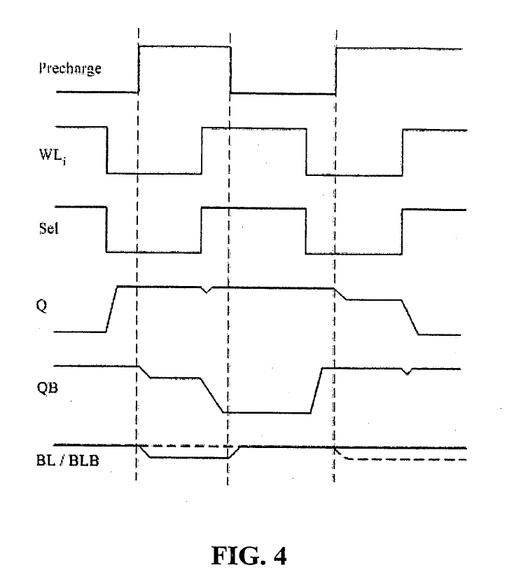

Referring to FIG. 2, the precharge circuit precharges the bit lines to V_{DD} before starting any read/write operation. The write cycle starts by turning Sel off to turn N3 26 off and to float the virtual ground node 25. While the precharge cycle is still on and the bit lines are both driven to V_{DD}, the word line WL is activated low, and therefore the two access PMOS transistors P3 and P4 are turned on to connect the bit lines BL and BLB to the cell nodes Q 23 and QB 24, respectively. Because the virtual ground 25 is floating with high impedance and PMOS transistor transfers a good V_{DD} signal, the cell nodes Q and QB are precharged “high” and equalized to V_{DD}. After the precharge cycle is ended, the write circuit drives one of the bit lines to V_{DD} and the complementary bit line to V_{DD}-ΔV according to the data to be written in the cell. The access PMOS transistors P3 and P4, which are still activated, transfer the bit line pair voltages to the corresponding cell nodes. Then WL is turned off, Sel is turned on, and the cell will amplify the small voltage difference, ΔV, between its nodes to full voltage swing by the two back-to-back inverters that act as a positive feed back amplifier inside the cell. The word line WL is turned off to isolate the bit line pair from the cell and therefore, the cell can amplify the small voltage swing on its nodes to full swing internally, while the bit line pair is completely isolated to reduce the power consumption. Depending on a very small voltage difference, ΔV, on the bit line pair leads to a large write power saving. During a write operation, the charges on the bit line capacitance are slightly reduced and therefore, the power required to re-charge this capacitance is small. The write power consumption of the present invention cell is expressed as follows:
P_{precharge-cell}=α_{BL}F_{write}V_{DD}{C_{BL}(ΔV)}
The conventional SRAM cell depends on completely discharging one of the bit lines “low” to guarantee a stable write operation. This means the bit line capacitor is almost completely discharged, and therefore a write operation consumes a lot of power to re-charge the bit line large capacitance. While in the present invention, the voltage swing on the bit lines is only ΔV and the write power dramatically decreases because the bit line capacitance is slightly discharged from V_{DD} to V_{DD}-ΔV and only needs a small amount of charges, charges=C_{BL}(ΔV), to be re-charged to V_{DD} again. FIG. 4 shows the signals waveforms during a write operation and the timing relation between them as discussed above. Precharge is the control signal for the precharge cycle and is active low.

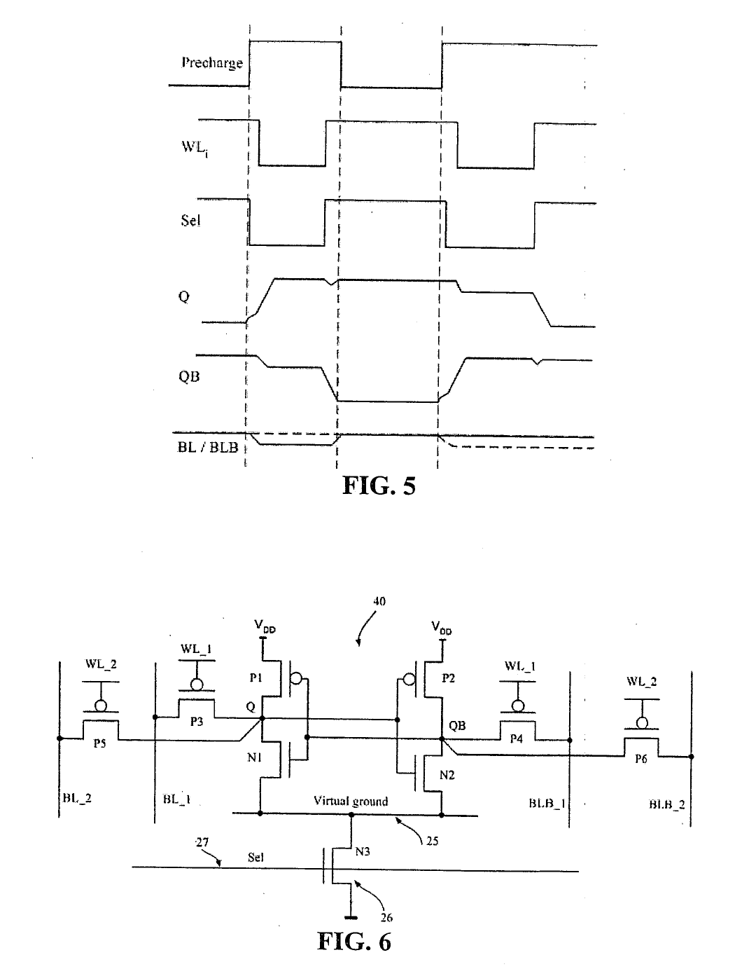

FIG. 5 illustrates another write scenario for the memory array in FIG. 3. The second scenario does not precharge the cell nodes before activating the write circuit. The word line WL is kept off during a precharge cycle. Then the write circuit drives the bit line pair to V_{DD} to V_{DD}-ΔV according to the data to be written in the cell and Sel signal 27 is turned off. Then, the word line WL is activated to transfer the voltage on the bit lines BL and BLB to the corresponding cell nodes Q and QB, respectively. Because the virtual ground node 25 is high impedance and no direct current path to the real ground, the cell nodes potentials can easily follow the corresponding bit line potentials and therefore, the cell can store a small voltage swing data. Then, the word line WL is turned off to isolate the small swing data inside the cell. Finally, the Sel signal is turned on to amplify the small voltage swing data to full voltage swing only inside the cell.

After a write operation is ended, the precharge circuit of the present invention only precharges the bit lines from V_{DD}-ΔV to V_{DD} and therefore, the required precharge time is much less that that for the conventional SRAM array. Therefore, the present invention memory array can be used as a high performance SRAM. Note that the precharge time after a read operation is the same as the conventional cell.

During a read operation, Sel is turned on if the cell switches from a sleep mode to an active mode, and therefore the cell re-stores its full voltage swing data. Then, word line WL is turned on to allow the internal node with “0” voltage to discharge the corresponding bit line until developing enough voltage difference at the sense amplifier inputs. Then, WL is turned off to end the read operation. The read operation is similar to the conventional cell but careful transistor sizing is needed to maintain the same read delay. Also, the static noise margin SNM for the present invention SRAM cell shown in FIG. 2 can be adjusted to be the same as the conventional 6T cell in prior art. Careful transistor sizing is required to maintain the static noise margin and read delay.

During a sleep mode, all N3 transistors from 26-1 to 26-L are turned off to reduce the leakage current through real ground node.

FIG. 6 illustrates a two-port SRAM cell 40 version of the low power SRAM cell in FIG. 2. The memory cell comprises cross-coupled inverters where the sources of the two pull down transistors are connected together to the virtual ground node 25. The source of the two pull up PMOS transistors P1 and P2 are connected to a supply voltage V_{DD}. The virtual ground 25 is coupled to the real ground through a NMOS N3 26 transistor; while Sel signal 27 controls the input of N3 26. The cell further comprises four PMOS access transistors P3, P4, P5, and P6. P3 and P4 couples between the first port bit line pair BL_1 and BLB_1 and the cell nodes Q and QB, respectively. WL_1 is the input to the first port access transistors P3 and P4. Similarly, P5 and P6 couples between the second port bit line pair BL_2 and BLB_2 and the cell nodes Q and QB, respectively. WL_2 is the input to the second port access transistors P5 and P6. The cell cannot perform read and write operations simultaneously. Write operation using the first or the second ports follows the same two scenarios explained above.

While the invention has been particularly shown and described with reference to the a number of illustrative embodiments therefore, it will be understood by those skilled in the art that various changes and embodiments in form or details may be made without departing from the spirit and scope of the invention. Reasonable variations and modifications are possible and arrangements within the scope of the foregoing disclosure, the drawings and the appended claims without departing from the spirit of the invention.

What is claimed is:

1. A static random access memory comprising:
two cross-coupled inverters, where the first inverter consist of the first p-channel (PMOS) transistor and a first n-channel (NMOS) transistor, and the second inverter consists of the second p-channel (PMOS) transistor and a second n-channel (NMOS) transistor;
first and second access p-channel (PMOS) transistors;
a Sel line,
a virtual ground line connected to the source of the first and second n-channel (NMOS) transistors of the first and second inverters;
a n-channel (NMOS) transistor couples between the virtual ground and the real ground, and a gate of the n-channel (NMOS) transistor coupled to the Sel line.
a first word line;
and bit line pair.

2. A static random access memory as claimed in 1,
Wherein said bit line pair comprises a bit line and a complementary bit line.

3. A static random access memory as claimed in 2,
Wherein the first access transistor couples bit line to the output of the first inverter, and the second access transistor couples complementary bit line to the output of the second inverter.

4. A static random access memory as claimed in 1,
Wherein said first word line is connected to the gates of the two access PMOS transistors.

5. A static random access memory as claimed in 1,
Wherein the cell reduces the write power consumption by reducing the voltage swing on the bit line pair to V_{DD} and V_{DD}-ΔV; and maintains the static noise margin by precharging the bit line pairs to V_{DD} and adjusting the transistor sizes.

6. A static random access memory (SRAM) row comprising:
A plurality of memory cells;
A plurality of virtual ground nodes;
A plurality of n-channel (NMOS) transistors;
A Sel signal; and
A word line signal.

7. The SRAM row of claim 6, wherein said memory cell comprises two cross-coupled inverters, two PMOS access transistors, and bit line pair.

8. The SRAM row of claim 7, wherein said cross-coupled inverters comprise:
a first inverter consist of a first pull up PMOS transistor and a first pull down NMOS transistor;
and a second inverter consists of a second pull up PMOS transistor and a second pull down NMOS transistor;
The output of the first inverter is connected to the input of the second inverter and the output of the second inverter is connected to the input of the first inverter;
The two pull down NMOS transistors are connected to a virtual ground node.

9. The SRAM row of claim 7, wherein said two PMOS access transistor comprising:
A first PMOS transistor couples between the output of the first inverter and bit line (BL);
A second PMOS transistor couples between the output of the second inverter and complementary bit line (BLB)

10. The SRAM row of claim 6, wherein said virtual ground nodes comprises K, where K equals 2, 4, 8, or 16, memory cells in the row are connected to the same virtual ground node.

11. The SRAM row of claim 6, wherein each n-channel (NMOS) transistor couples between one virtual ground node and real ground, Sel signal is an input coupled to the gate of the n-channel (NMOS) transistor.

12. The SRAM row of claim 6, wherein Sel signal is an input to all n-channel (NMOS) transistors in the row.

13. The SRAM row of claim 6, wherein word line is connected to all the gates of the access PMOS transistors for all cells in the row.

14. The SRAM row of claim 6, further comprising a memory cell array.

15. A static random access memory as claimed in 1, wherein said memory is a dual port random access memory.

16. A static random access memory as claimed in 15 further comprises:
a third and fourth PMOS access transistors;
a second word line;
and a second bit line pair.

17. A static random access memory as claimed in 16, wherein said bit line pair comprises
a bit line and a complementary bit line.
